(19) United States
(12) Patent Application Publication
(10) Pub. No.: US 2007/0257335 A1
(43) Pub. Date: Nov. 8, 2007

(54) Illuminator and Manufacturing Method

(76) Inventor: Peter O'Brien, Country Cork (IE)

Correspondence Address: JACOBSON HOLMAN PLLC, 400 SEVENTH STREET N.W., SUITE 600, WASHINGTON, DC, 20004, US

(21) Appl. No.: 11/666,499

(22) PCT Filed: Oct. 28, 2005
(86) PCT No.: PCT/IE05/00121

§ 371 Date: Apr. 27, 2007

(30) Foreign Application Priority Data
Oct. 29, 2004 (IE) 2004/0724

(51) Int. Cl. H01L 21/98; H01L 21/00

(52) U.S. Cl. 257/618; 438/34; 438/618; 257/E21.001; 257/E21.705; 257/E27.001

(57) ABSTRACT

An illuminator (1) is manufactured by embossing an aluminium preform to provide a structured substrate base (21) with cavities (25) for LEDs and recesses (26) for tracks. The substrate is anodised to provide an aluminium oxide insulating layer (30) over the structured surface. A metal layer (35) is then applied over the insulating layer (30), and this is etched to leave metal pads in the cavities and tracks in the recesses (26). LEDs (50) are placed in the cavities and they are wire-bonded to the exposed metal tracks. This manufacturing method allows versatility in choice of configuration of 5 illuminator by simple embossing a desired substrate shape. Also, the anodisation provides an excellent and durable insulating layer, which has the major benefit of being conformal with the structured surface.

### FIELD OF THE INVENTION

The invention relates to illuminators and to their manufacture

### Prior Art Discussion

High brightness LED arrays are required for a broad range of applications. These include general illumination (incandescent lamp replacement), illumination for machine vision, radiation induced curing of materials or epoxies (ultra-violet curing), and illumination for biosensing and medical therapies. High brightness is achieved by placing large numbers of LED chips in close proximity on an optical sub-mount or package. An optical package should serve the three important functions of providing an electrical contact, providing an optical reflector, and efficiently dissipating heat generated by the LEDs.

Electrical connection of large numbers of LEDs in close proximity is often achieved by implementing a series-parallel circuit configuration. In this configuration, a number of LEDs are connected in series to form a chain and a number of chains are then connected in parallel to form the complete array. This circuit configuration is desirable as there can be deviations in the switch-on voltages across a large number of LEDs. The series-parallel circuit configuration requires that individual LEDs be electrically isolated from their neighbours on the optical package.

LEDs tend to emit optical radiation equally in all directions. However, most applications require that the output power from an LED be forward-directed. Therefore, it is desirable that LEDs be packaged within an optical reflector. An example is a 5 mm epoxy package having a metal reflector cup in which the LED is bonded.

Packaging a large numbers of LEDs within close proximity generates large amounts of heat. This heat must be removed as it can have a deleterious effect on the performance and reliability of the LEDs. Most of this is dissipated through the optical package.

Combining the above requirements for an efficient LED optical array package poses a major technical challenge. The package must provide electrical contact to isolated devices bonded within an optical reflector, while being capable of dissipating large amounts of heat.

At present, it is known to provide a metal base, over which a polymer layer is applied to provide an electrical insulator for the LEDs. However, while the polymer is a good electrical insulator it is poor at conducting away heat and also, it is difficult to achieve a uniform depth or thickness of polymer over the metal. For example, it is extremely difficult to achieve a uniform thickness of polymer over a metal structure that has cavities, as the polymer will well-up within the cavities, making polymers only suitable for planar metal substrates.

The invention is therefore directed towards providing an improved illuminator and/or manufacturing process.

### SUMMARY OF THE INVENTION

According to the invention, there is provided a method of manufacturing an illuminator substrate for supporting a plurality of bare die light emitting diodes, the method comprising the steps of:
providing a substrate base comprising at least a layer of aluminium material having a surface, said substrate being structured in which the aluminium surface has cavities for the diodes;
anodising said aluminium surface to provide an aluminium oxide insulating layer, and
selectively coating the insulating layer with a metal to provide diode pads in the cavities and tracks for the diodes.

In one embodiment, the substrate base cavities comprise tapered side walls.

In another embodiment, the substrate base comprises recesses for the tracks, and metal is coated on the insulating layer to provide the tracks.

In a further embodiment, the substrate base is provided by embossing a blank with a master having a configuration conforming to the desired structured pattern of the substrate base.

In one embodiment, the method comprises the further step of cleaning the embossed substrate base before anodising.

In another embodiment, the substrate base is ultrasonically treated to create implosive sites on the surface at which contamination is agitated.

In a further embodiment, the method comprises the further step of chemically treating the surface to remove contaminants.

In one embodiment, the surface is treated with a mixture of phosphoric acid and nitric acid.

In another embodiment, the surface treatment leaves a residual layer of aluminium nitrates and oxides with sufficient thickness to prevent oxidation before formation of the insulating layer.

In a further embodiment, comprises a secondary pretreatment step of step of immersing the substrate base in an acidic bath.

In one embodiment, the bath comprises sodium silicate, sodium carbonate, and anionic surfactants.

In another embodiment, the bath is maintained at an elevated temperature in the range of 45° C. to 50° C.

In a further embodiment, the method comprises the further step of etching the substrate base surface before anodising to promote bond strength between the substrate and the insulating layer.

In one embodiment, the etching step comprises treating the substrate with sodium hydroxide.

In another embodiment, said treatment is carried out at an elevated temperature in the range of 50° C. and 60° C.

In a further embodiment, the method comprises the further step, after etching, of immersing the substrate base in a nitric acid solution.

In one embodiment, the anodising step comprises electrolysis treatment of the substrate base.

In another embodiment, an electrolytic bath for electrolysis comprises sulphuric acid and oxalic acid.

In a further embodiment, the bath is maintained at a temperature in the range of 20° C. and 25° C.

In one embodiment, the current density is in the range of 1.8 A/m² to 2.7 A/m².

In another embodiment, the applied voltage for electrolysis is in the range of 20V to 30V.

In a further embodiment, electrolysis is controlled to achieve an insulating layer film formation rate in the range of 40 to 50 microns/hr.

In one embodiment, the insulating layer thickness is in the range of 1 to 100 microns.

In another embodiment, the insulating layer thickness is in the range of 10 to 30 microns.

In a further embodiment, the insulating layer thickness is approximately 20 microns.

In one embodiment, the substrate base with insulating layer is treated post-anodising by heat treatment by storage in an oven at a temperature in the range of 70° C. to 90° C.

In another embodiment, the insulating layer is selectively metal coated by initially applying a blanket metal coating and subsequently selectively removing the metal.

In a further embodiment, the blanket of metal is applied by sputtering.

In one embodiment, the metal blanket is treated by photolithography and chemical etching.

In another embodiment, the metal blanket is selectively abraded to expose the underlying insulating layer.

In a further embodiment, the metal blanket is abraded at raised surfaces.

In one embodiment, the raised surfaces are co-planar.

In another embodiment, the substrate base comprises only aluminium.

In a further embodiment, the substrate base comprises an aluminium layer over a different metal.

In one embodiment, the different metal is copper.

In another aspect, the invention provides a method of producing an illuminator comprising the steps of:
producing a substrate in any method as defined above,
placing bare die light emitting diodes in the cavities, and
placing wire bonds between the diodes and the tracks

In a further aspect, the invention provides an illuminator substrate comprising:
a substrate base comprising at least a layer of aluminium having a surface, said surface being structured with cavities for bare die light emitting diodes and recesses for electrical tracks,
an insulating layer of aluminium oxide over the substrate base; and
conductive pads in the cavities and tracks in the track recesses on the insulating layer.

### DETAILED DESCRIPTION OF THE INVENTION

### BRIEF DESCRIPTION OF THE DRAWINGS

The invention will be more clearly understood from the following description of some embodiments thereof, given by way of example only with reference to the accompanying drawings in which:

FIG. 1 is a plan view of an illuminator of the invention;

FIGS. 2 to 10 inclusive are diagrams illustrating a method for manufacturing the illuminator;

FIG. 11 is a diagram illustrating configuration of an embossing master used in the process;

FIG. 12 is a photograph of a cross-section through an illuminator;

FIG. 13 is a plan view of an alternative illuminator of the invention;

FIG. 14 is a perspective view of a still further illuminator;

FIGS. 15 and 16 are plan views of further illuminator configurations; and

FIG. 17 is a set of plots of optical reflectivity of various metals.

### DESCRIPTION OF THE EMBODIMENTS

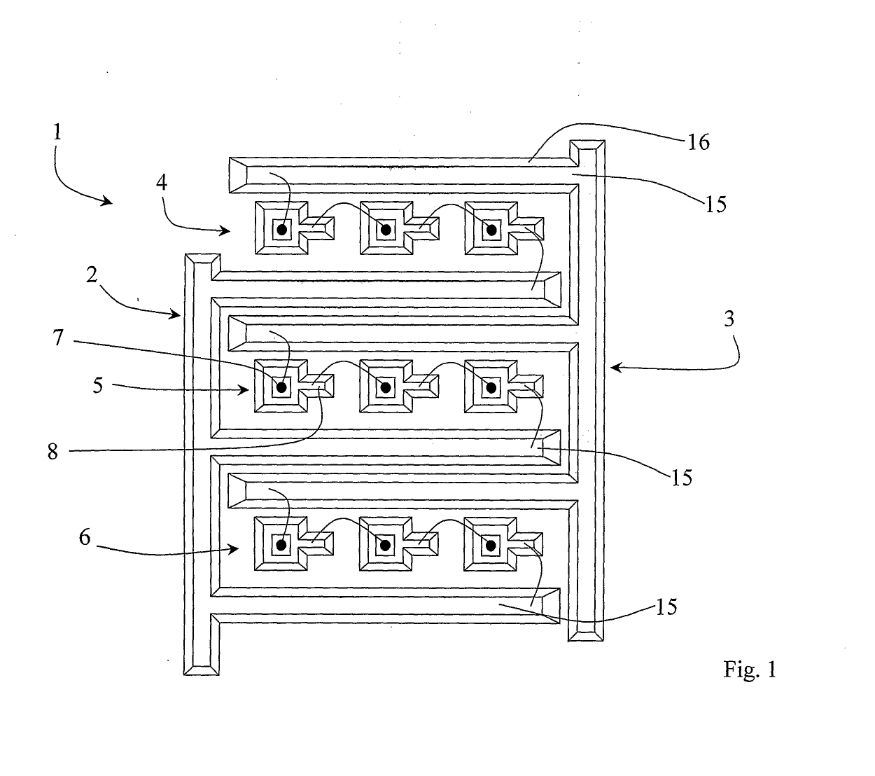

Referring to FIG. 1 an illuminator 1 comprises a substrate having electrically isolated recessed ground and power rails 2 and 3 across which are three series 4, 5, and 6 of bare die diodes in cavities. Each series comprises three LEDs 7, for each of which there is a recessed metal contact 8. Each end LED is wire-bonded to a rail 2 or 3. Each rail 2, 3 comprises a conductor 15 in a recess, and substrate side walls 16.

In this embodiment the substrate base is bulk aluminium. However, it may alternatively be of a different bulk material (such as copper) coated with aluminium. In this alternative embodiment, the illuminator would benefit from the higher thermal conductivity of copper, and it would be simple to bond the aluminium layer to the copper underneath.

The electrical isolator regions are part of an anodisation layer over the aluminium surface. The electrical conductor regions in the cavities and rails are part of a metal coating over the anodisation. The anodisation layer (aluminium oxide Al₂O₃) is a good thermal conductor and electrical insulator. The anodisation step allows excellent uniformity in the A₂O₃ thickness, conforming to the aluminium substrate base structured surface pattern. Particularly good thermal conduction and electrical insulation is achieved by anodising in a “hard” anodisation process, described in more detail below. This is particularly advantageous as it avoids cracking or scratching, causing electrical shorts, especially in a manufacturing process.

The illuminator configuration of FIG. 1 is merely one example of a range of different configurations which could be manufactured by a process of the invention. The metal layer can be applied on the Al₂O₃ in one of a range of techniques, including sputtering, electroplating (with use of a seed metal layer), or thermal evaporation.

The metal can be selectively removed by simply abrading or polishing away the metal layer where an electrical insulator is required on the raised surfaces. This is particularly advantageous because it allows complex patterns of conductors and insulators to be formed in a simple manufacturing sequence of embossing aluminium, anodising, metallising, and abrading.

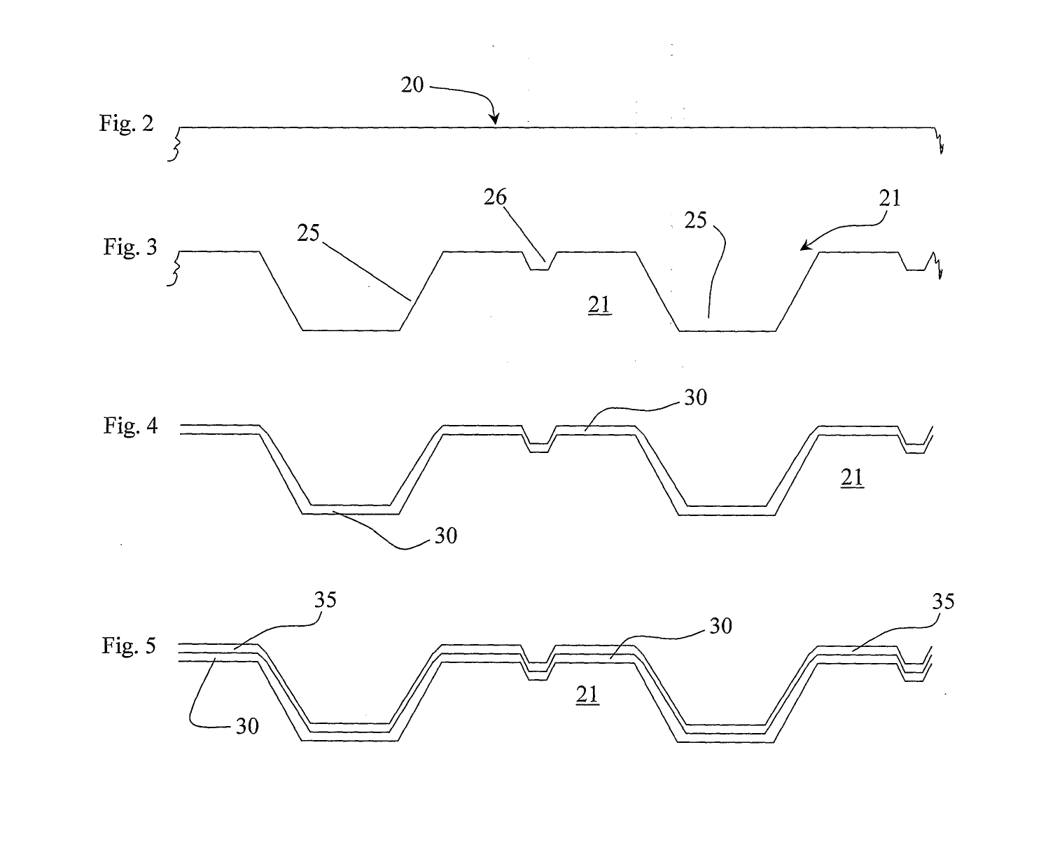

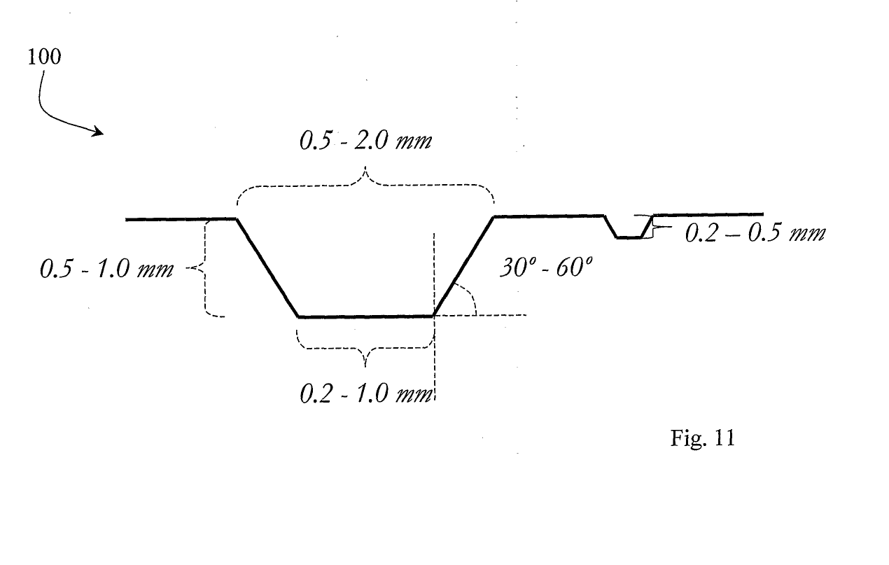

Referring to FIGS. 2 to 10 inclusive on aluminium blank 20 is provided, and it is embossed using a master such as a master 100 shown in FIG. 11. The resultant substrate base structured pattern is shown in FIG. 3, including LED cavities 25 and rail/track recesses 26. Anodising the substrate base 21 results in a uniform, conformal, Al₂O₃, insulating layer 30 of 20 μm thickness as shown in FIG. 4. The general thickness range is 1-100 μm. An aluminium coating 35 is then applied by sputtering as shown in FIG. 5. This may alternatively be of a different metal such as silver.

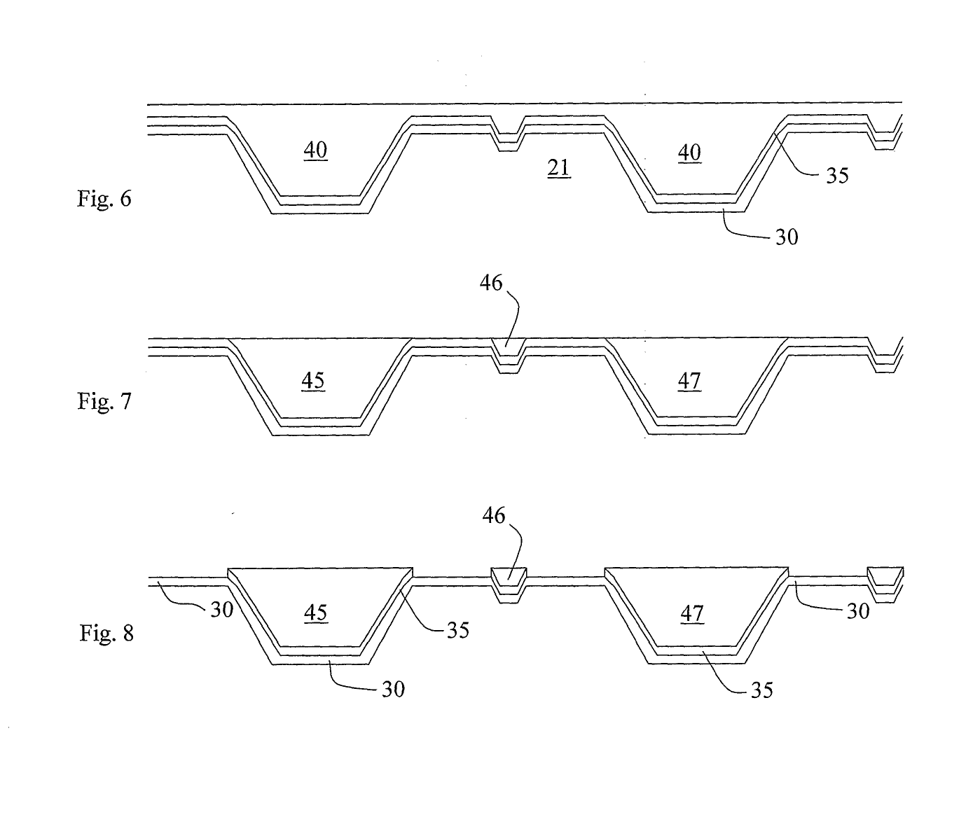

As shown in FIG. 6, photoresist 40 is then blanket coated over the metal layer 35, and this is planarised as shown in FIG. 7. As shown in FIG. 8 exposed metal 35 is etched away, leaving metal 35 in the LED cavities isolated from that in the rail recesses. Polishing (abrading) may be used instead of or in addition to etching. There remains photoresist 45 and 47 in the LED cavities, and 46 in the rail recesses.

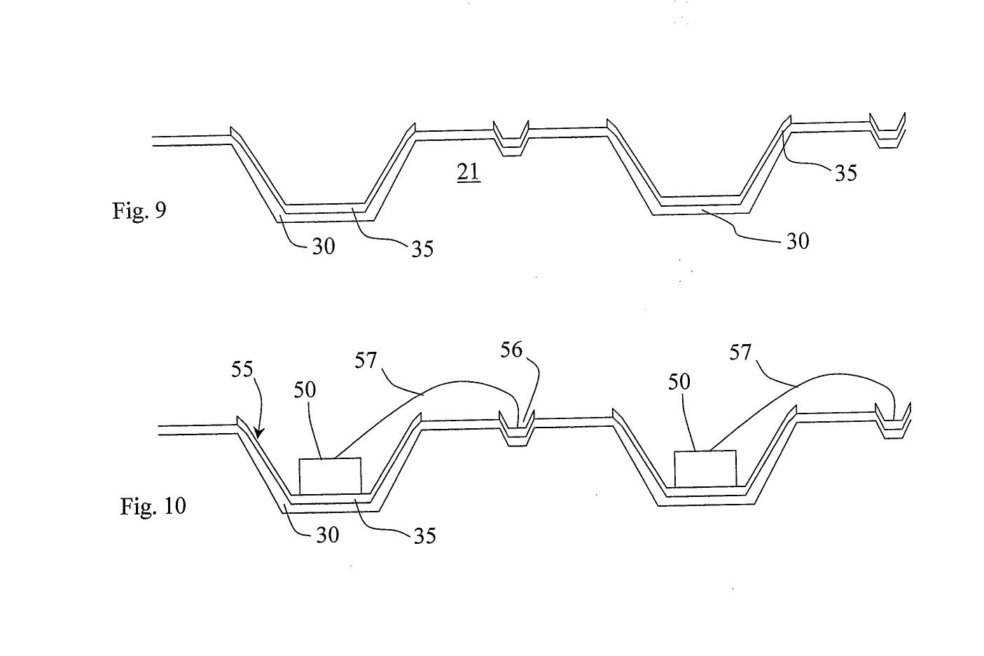

As shown in FIG. 9 the photoresist is removed, leaving the metal 35 in the recesses exposed. This completes production of the illuminator substrate.

The final illuminator, as shown in FIG. 10, comprises LED cavities 55 each having a bare die LED 50 and a wire bond 57 to a rail 56. This arrangement is different from that of FIG. 1, however, the same manufacturing techniques apply.

Embossing

Aluminium Preform

The starting material or preform is a flat aluminium part prepared to the desired illuminator shape. For example, a ring-light substrate will consist of an annular preform and a line-light will consist of a long rectangular preform—the dimensions of these preforms will depend on the dimensions of illuminator. In this embodiment, the aluminium preform has approximate dimensions of 2.5 cm×2.5 cm×1 cm. An advantage of the invention is that the Al substrate is of high strength even in very small and/or complex configurations. This allows production of illuminators for applications such as endoscopes or boroscopes in the medical device field.

High purity aluminium is used as this improves the anodising process. Alloys of aluminium should be avoided as these materials give poor quality anodised layers and impede the anodising process. Aluminium purity levels should be greater than 99%.

Embossing the aluminium preform requires a hard metal master that incorporates a negative of the features that will be embossed on the surface of the substrate. Materials such as toughened steel can be used for the master. FIG. 11 shows the master used in one embodiment. It is fabricated from a toughened steel block and has been precision machined to produce small pyramidal structures that will emboss pyramidal reflector cavities into the aluminium preform. Additional features which can be included on the embossing master include, (i) raised tracks for inter device electrical connection, (ii) stand-off pads for wire-bonding and (iii) recessed grids to facilitate electrical isolation of adjacent LED devices.

The embossing process involves bringing the master into contact with the aluminium preform. Sufficient and uniform pressure is applied to ensure that all areas of the master come into contact with the substrate, as otherwise a non-uniform surface will result. No heat is applied during the embossing process. Too low an embossing pressure will result in a non-uniform surface profile especially near recessed structures such as reflector cavities. The embossing process moves aluminium material from the surface to the edges of the substrate. The overall volume of aluminium material being moved is small (dependent on the size and density of cavities and other embossed-structures) and this has minimum effect on the shape of the substrate. Additional machining can be done if it is necessary to remove this material for cosmetic purposes.

Anodisation

Aluminium

Aluminium atomic number 13 is a light, white metal, having an electrical conductivity of 0.382×10⁻⁸k/S at 298K, this is seen to be quite high when compared to gold at 0.42 on the same scale. It is also reactive to oxygen in air, forming aluminium oxide:
2Al+3O₂→Al₂O₃ (1)

This oxide is an electrical insulator and can also be formed by making the substrate base anodic in a suitable electrolyte. The purer the aluminium the more suitable it is for this process e.g. LM 0 99.5% w/w.

Pretreatment

Following embossing, the aluminium surface can have many types of organic matter present on the surface such as drawing compounds from the mill, oils, and greases. These are removed by using a neutral pH soak cleaner (being amphoteric aluminium will dissolve in both acids and alkalis). Ultrasonics are also employed at this stage to create implosive sites at the substrate surface to mechanically agitate contamination. A clean water break shows that the surface of the metal is sufficiently clean to proceed.

In some cases a secondary soak clean may be employed.

Chemical Brightening

Operating at a temperature of some 65-75° C. this process follows pre-treatment and uses a mixture of phosphoric and nitric acids. During immersion heavy oxides are removed to reveal the true, bright lustre associated with all metals. A very thin layer of aluminium nitrates and oxides forms, preventing re-oxidation on contact with the atmosphere.

Secondary Pre-treatment

During handling, inspection, or physical movement it is possible to contaminate the brightened surface. As a precaution on entering the anodising line a secondary cleaner is used consisting of:
Sodium silicate,
EDTA, (Ethylenediaminetetraacetic Acid, a sequestering agent)
sodium carbonate, and
anionic surfactants.

This is heated to 45-50° C., and the immersion time (2-3 min.) is dependant on the degree of contamination present.

Caustic Etch

Etching is a means of producing a micro-rough, chemically active surface to promote bond strength with the subsequent anodic layer. If anodisation is ineffective for any reason the coating may fracture on substrate deformation. This is clearly not conducive to consistent electrical resistance. Etching uses primarily an aqueous solution of sodium hydroxide controlled thermostatically between 50° C. and 60° C.

Complexing agents such as sodium gluconate may be added to increase the capacity and reduce the effects of common ions. No aluminium is 100% pure, and so most of the common alloying elements such as copper and iron will form black oxides in these conditions. These may appear as a smut on the aluminium surface that needs to be removed, as set out below.

Desmut

To prevent any smut interfering with the anodising process the piece is immersed in a solution of 50% v/v nitric acid, most nitrates of metals are water soluble and therefore removed on rinsing or during immersion. The following reactions occur
CuO+2HNO₃→Cu(NO₃)₂+H₂O (2)
Fe₂O₃+6HNO₃→2Fe(NO₃)₃+3H₂O (3)

All wet chemical processes are followed by rinsing.

Anodising.

Anodising is the controlled formation of aluminium oxide using electrolysis as in (1) above. The part is made positive and therefore forms ions as follows:
Al−3e⁻→Al^{3 +} (4)

Due to the acidity of the solution water is also electrolysed such that oxygen is liberated at the workface and the oxide formed as in (1) above.

The rate of formation of the film is dependant on the applied voltage, surface geometry, and the electrolyte composition. The oxide has a density approximately half that of the substrate, so for approximately every micron of metal removed two microns are produced, somewhat dependant on the alloy.

In the process it was decided to use the densest coating, known as “hard” anodising. This helps to ensure integrity of the anodisation layer, avoiding potential defects such as punch-through. The electrolyte was operated as follows:

Solution Composition

| | |
|---|---|
| Pure sulphuric acid sg 1.84 | 100 ml/l |
| Oxalic acid | 50 g/l |
| Fume suppressant | 0.2-0.3 ml/l |
| Balance DI water | |
| Anodic Current Density | 1.8 A/m² to 2.7 A/m² |
| Voltage | 40-50 V |
| Temperature | 20-25° C. |
| Film Formation | 40-50 μm/hr |
| Agitation | Vigorous air |
| Max. Aluminium Content | 20 g/l |
| Max. Chloride | 100 ppm |
| Cathodes | Pure Al |
| Tank Construction | Polypropylene |
| Rectification | Ripple <1% |

Rinsing and Finishing

Following anodising to approximately 20 μm as indicated by eddy current measurement of a test piece the parts are thoroughly rinsed in tap water followed by Deionised water containing less that 1 ppm chloride. The film is inspected for uniformity, pressurised air dried and oven stoved at 80° C. for 30 mins in an air circulating oven.

Metal Coating

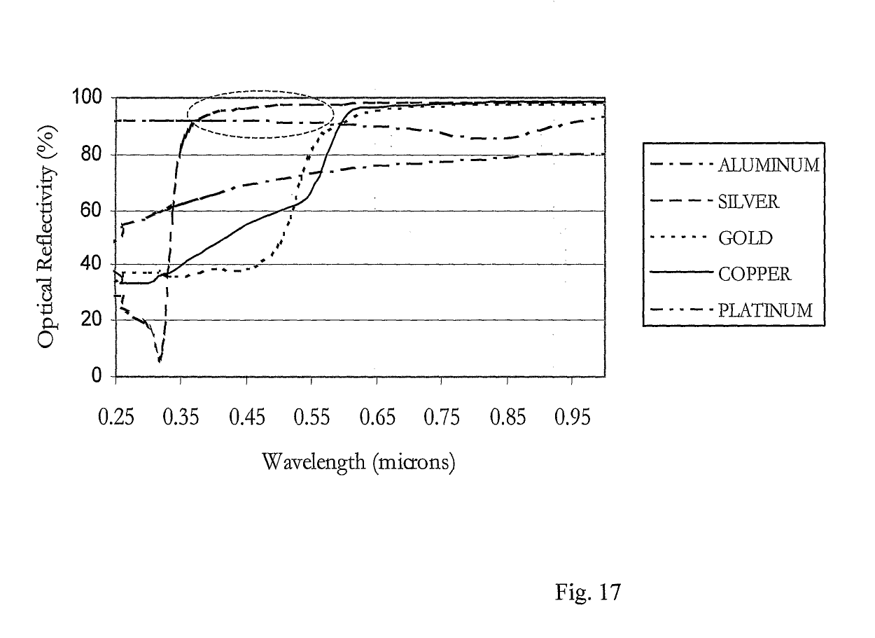

After anodising, a thin layer of metal is coated over the embossed surface. The purpose of this metal layer is to provide electrical contact pads and to maximise optical reflectivity of the cavities. The metal layer thickness can vary, a thin layer (approximately 1 micron) is cost effective and a thick layer (approximately 50 microns) provides optimum heat dissipation. We chose an intermediate thickness of 5 microns. This is can be deposited relatively quickly (suiting a production environment) and still provides sufficient heat dissipation and optical reflecting properties. The choice of metal is dependent on the emission wavelength of the LEDs. For example, gold should not be used for green (approximately 530 nm) and blue (approximately 470 nm) LEDs, as gold absorbs a large percentage of optical power at these wavelength. Silver or aluminium metals are ideal as they have relatively little optical absorption at these wavelengths as shown in FIG. 17.

For the method of deposition we chose sputter coating as it ensures all regions are coated with an equal thickness of metal. Other techniques such as thermal or electron-beam evaporation are not suitable as they suffer from shadowing effects (surfaces not visible to the evaporation source will not be coated).

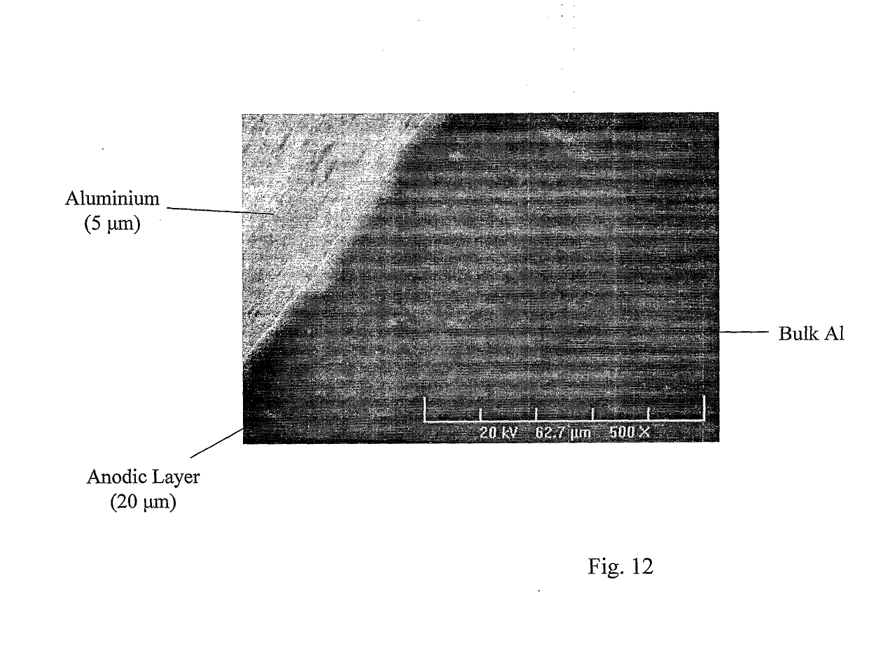

In this embodiment we chose to sputter coat 5 microns of aluminium over the entire aluminium oxide surface. Later inspection using a high-resolution microscope indicated that the aluminium layer was evenly coated over the entire surface. The aluminium metal layer exhibited excellent adhesion to the anodised layer (evaluated using standard tape-pull tests). FIG. 12 is an electron-microscope image showing a cross section of a micro-reflector cavity, showing a sidewall of the micro-reflector cavity. It is evident that the anodised layer is dense and adheres well to the bulk and the sputtered aluminium layers. The anodised layer is also non-porous and makes an excellent electrical insulator while providing good thermal conductivity.

Metal Contact Definition

(Photolithography/Chemical Etch and Mechanical Polishing)

Following deposition, the metal layer forms a contiguous layer over the embossed and anodised aluminium substrate base. This layer must be processed further to define electrical contact pads on which the LEDs can be bonded and for electrical tracks running between individual LED contact pads. A number of processes can be used to define these metal features.

Photolithography: As shown in FIGS. 6 to 8, this involves deposition of a thick layer of negative photoresist over the entire embossed surface. Alternatively dry film photoresist can be laminated over the embossed surface. The photoresist layer is exposed to UV light that has a pattern of the desired features. The exposed photoresist region remains on the surface following post-exposure treatment with chemicals. The remaining photoresist protects the metal during the chemical etching process which removes the metal in the unprotected regions. The aluminium metal 35 can be etched using a dilute solution of sodium hydroxide (NaOH). The metal etching process is stopped once the anodised layer 30 is exposed. This end-point is visible as the anodised layer 30 has a white colour. Additional checks can be made to ensure the anodised layer 30 has been reached by measuring high electrical isolation/resistance (Mega-Ohms) between metal contact pads.

Mechanical polishing may alternatively be used. In these embodiments, the embossing process provides recessed LED bond pads and electrical tracks. These are the regions where the metal layer 35 remains. Therefore, polishing or abrading the surface removes metal from regions that must provide electrical isolation between LED contact pads and electrical tracks. It will be apparent from FIGS. 7 and 8 that the raised grids can alternatively be polished to produce an electrical isolation region between adjacent LED contact pads.

The entire embossed surface is coated with a thick layer of negative photoresist. The thickness is determined by ensuring that all embossed features are fully covered and a planar layer of photoresist remains over the surface. The photoresist is relatively soft and can be polished back easily while still providing mechanical protection to the metal layer in the LED contact pads and electrical tracks. The polishing material consists of different grades of aluminium oxide (Al₂O₃) powder. Polishing starts with a coarse powder grade (approximately 20 microns diameter) mixed in water to form a slurry and finished with fine powder grade (approximately 1 micron). This sequenced polishing process produces a high quality mirror-like finish on the aluminium substrate. In this work, the polishing process is stopped after removing both metal and anodised layers and the bulk aluminium substrate is revealed. Resistance measurements indicate very high levels of electrical isolation between adjacent LED bond pads—resistance levels in the Mega-Ohm between bond pads were measured with 100% repeatability over the entire surface.

The mechanical polishing process enables manufacture of the necessary series-parallel circuit arrangement on a single work piece. This manufacturing approach can also be employed for other illuminator geometries.

LED Attachment and Wirebonding

The above process provides a substrate, and an illuminator is completed as follows. LEDs are attached using silver loaded epoxy or reflow solders—similar to standard LED attachment techniques. Wirebonding is used to attach a top electrical contact to the LED. In this work, silver loaded epoxy was used for LED attachment. 25 micron diameter Gold wire was attached to the top of individual LEDs using an ultrasonic Wirebonding system.

Electrical and Optical Testing

A 2×6 LED array with peak wavelength of 465 nm was electrically and optically tested to confirm the principles of operation and optical stability. The array was configured in a series parallel arrangement. The individual LEDs are recommended to operate at 20 mA current under a forward voltage of approximately 3.3 Volts. In this series of tests, a total forward voltage of 19.1 Volts was required to drive 40 mA through the array (20 mA per 6 element LED series). This indicated negligible resistance from the LED package. The optical power appeared uniform across all LEDs (this was observed under low current/low power output. Finally, a thermistor was placed in contact with the bulk aluminium substrate to monitor temperature under normal operating conditions—no additional heat-sink was required. A temperature change of less than 1° C. was observed during the measurement time (approximately 30 minutes).

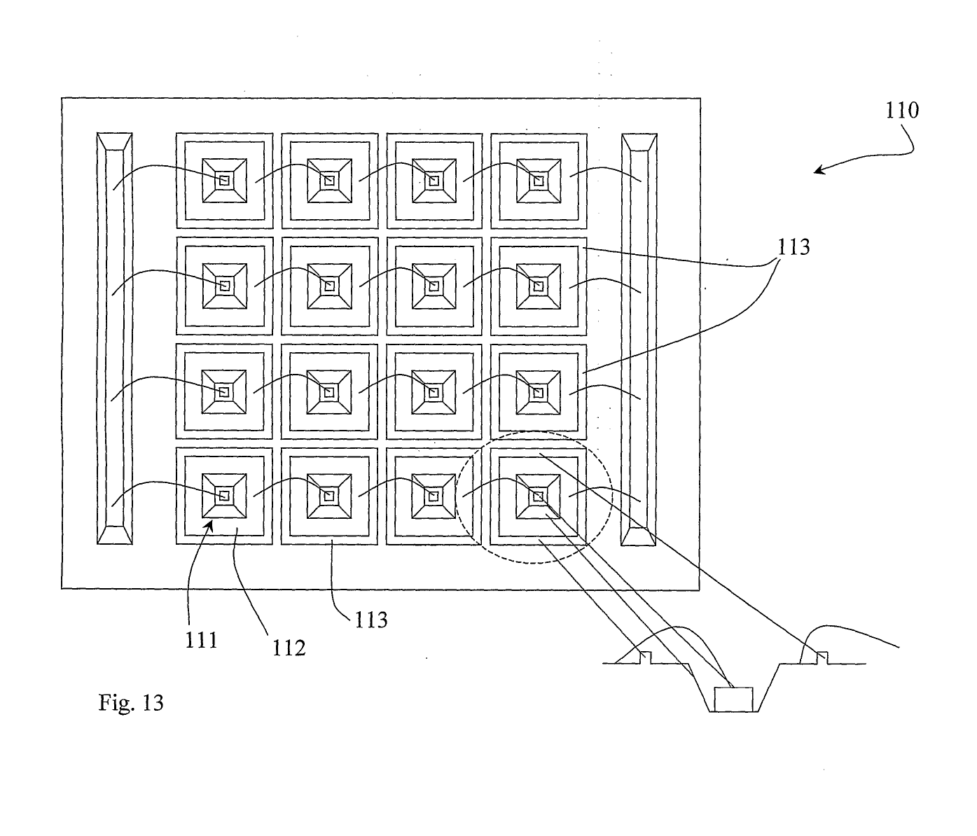

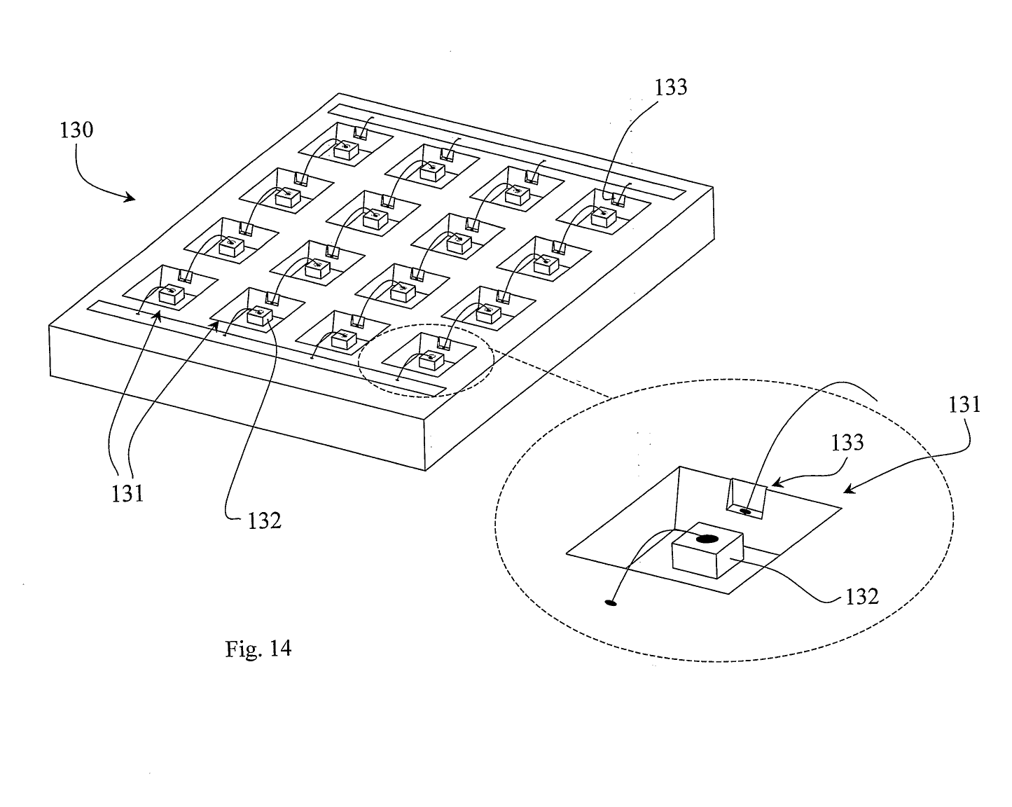

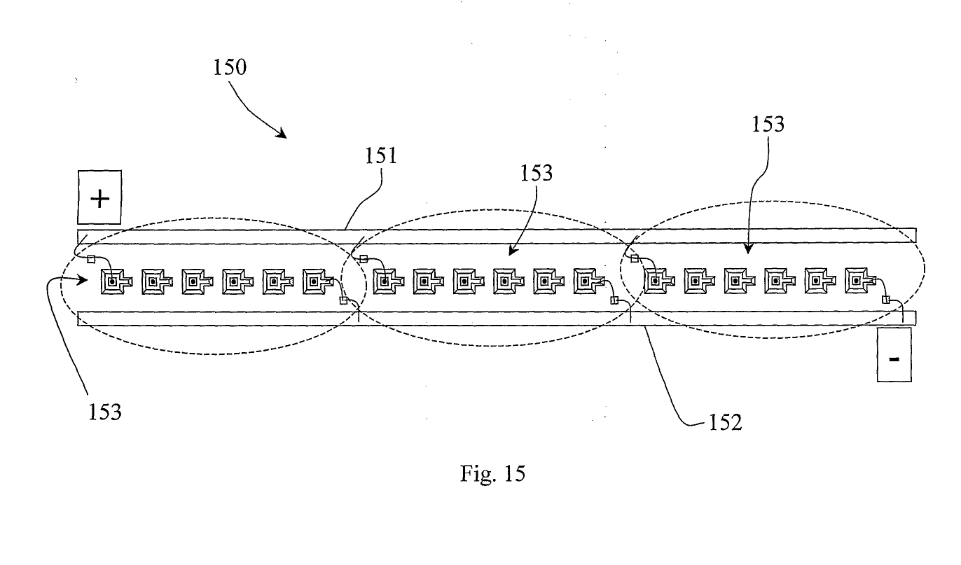

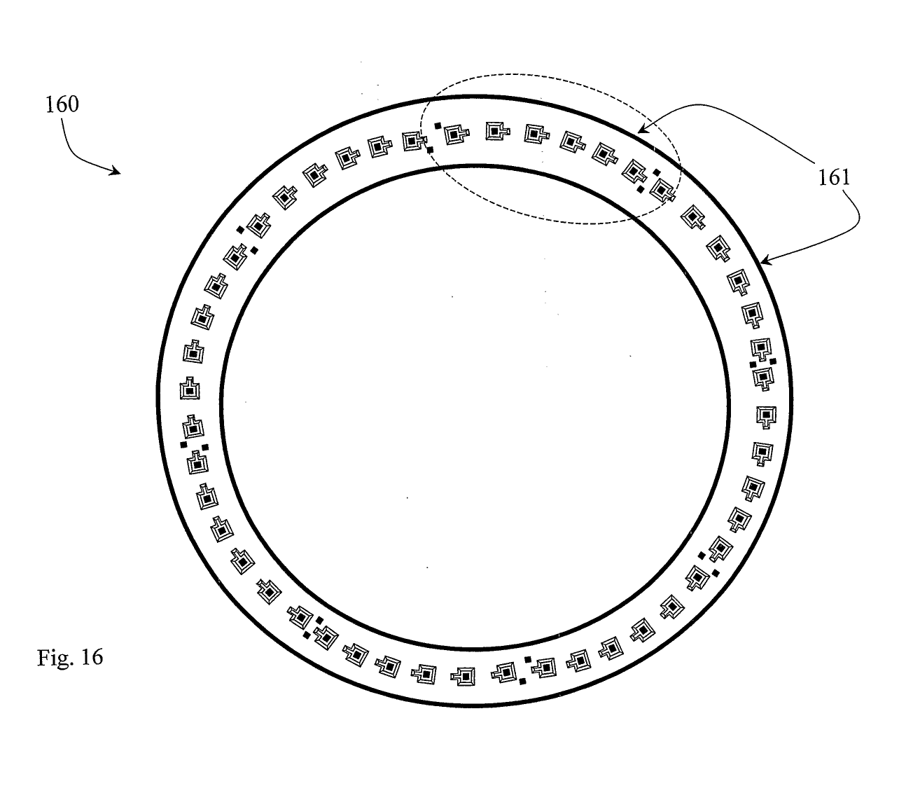

The fact that the process allows production of a variety of different illuminator configurations is demonstrated by FIGS. 13 to 16. In FIG. 13 an illuminator 110 has cavities 111 around which are shoulder areas 112 and raised insulating ridges 113. In this embodiment the ridge top surfaces are polished (abraded) to reveal the anodic insulating layer for isolation of the LEDs. An illuminator 130, shown in FIG. 14 has cavities 131 with LEDs 132 and recessed ledges 133 with exposed metal for wire bond attachment. FIG. 15 shows a linear illuminator 150 having tracks 151 and 152 on either side of three series 153 of LEDs. FIG. 16 shows an annular illuminator 160 having an LED series circuit of LEDs 161.

It will be appreciated that the invention provides for manufacture of illuminators with excellent versatility in choice of physical configuration. This allows choice of a relatively large illuminator for applications such as machine vision. An alternative configuration is a very small illuminator for mounting on a medical device for internal use, such as an endoscope or a boroscope. The metal substrate provides sufficient strength even for small and complex configurations. Furthermore, the invention allows very simple manufacturing with excellent quality arising from the ease with which an insulating layer can be achieved by virtue of anodising. Such an insulating layer has excellent physical integrity, achieving a very low chance of a defect giving rise to a short circuit between the top metal and the underlying substrate, or between diodes or tracks. Also, the operation of selectively applying the top metal layer is relatively simple, whether etching or polishing techniques are used.

The invention is not limited to the embodiments described but may be varied in construction and detail. For example, the initial preform may be of integral aluminium or it may comprise a body of a different material such as copper and a top layer of aluminium.

1-37. (canceled)

38. A method of manufacturing an illuminator substrate for supporting a plurality of bare die light emitting diodes, the method comprising the steps of:
providing a substrate base comprising at least a layer of aluminium material having a surface, said substrate being structured in which the aluminium surface has cavities for the diodes;
anodising said aluminium surface to provide an aluminium oxide insulating layer including in said cavities, and
selectively coating the insulating layer with a metal to provide diode pads in the cavities and tracks for the diodes.

39. The method as claimed in claim 38, wherein the substrate base cavities comprise tapered side walls.

40. The method as claimed in claim 38, wherein the substrate base comprises recesses for the tracks, and metal is coated on the insulating layer to provide the tracks.

41. The method as claimed in claim 38, wherein the substrate base is provided by embossing a blank with a master having a configuration conforming to the desired structured pattern of the substrate base.

42. The method as claimed in claim 38, comprising the further step of cleaning the embossed substrate base before anodising.

43. The method as claimed in claim 38, comprising the further step of cleaning the embossed substrate base before anodising; and wherein the substrate base is ultrasonically treated to create implosive sites on the surface at which contamination is agitated.

44. The method as claimed in claim 38, comprising the further step of chemically treating the surface to remove contaminants.

45. The method as claimed in claim 38, comprising the further step of chemically treating the surface to remove contaminants; and wherein the surface is treated with a mixture of phosphoric acid and nitric acid.

46. The method as claimed in claim 38, comprising the further step of chemically treating the surface to remove contaminants; and wherein the surface treatment leaves a residual layer of aluminium nitrates and oxides with sufficient thickness to prevent oxidation before formation of the insulating layer.

47. The method as claimed in claim 38, comprising the further step of chemically treating the surface to remove contaminants; and comprising a secondary pre-treatment step of step of immersing the substrate base in an acidic bath.

48. The method as claimed in claim 47, wherein the bath comprises sodium silicate, sodium carbonate, and anionic surfactants.

49. The method as claimed in claims 47, wherein the bath is maintained at an elevated temperature in the range of 45° C. to 50° C.

50. The method as claimed in claim 38, comprising the further step of etching the substrate base surface before anodising to promote bond strength between the substrate and the insulating layer.

51. The method as claimed in claim 38, comprising the further step of etching the substrate base surface before anodising to promote bond strength between the substrate and the insulating layer; and wherein the etching step comprises treating the substrate with sodium hydroxide.

52. The method as claimed in claim 51, wherein said treatment is carried out at an elevated temperature in the range of 50° C. and 60° C.

53. The method as claimed in claim 38, comprising the further step of etching the substrate base surface before anodising to promote bond strength between the substrate and the insulating layer; and comprising the further step, after etching, of immersing the substrate base in a nitric acid solution.

54. The method as claimed in claim 38, wherein the anodising step comprises electrolysis treatment of the substrate base.

55. The method as claimed in claim 38, wherein the anodising step comprises electrolysis treatment of the substrate base; and wherein an electrolytic bath for electrolysis comprises sulphuric acid and oxalic acid.

56. The method as claimed in claim 55, wherein the bath is maintained at a temperature in the range of 20° C. and 25° C.

57. The method as claimed in claim 54, wherein the current density is in the range of 1.8 A/m² to 2.7 A/m².

58. The method as claimed in claim 54, wherein the applied voltage for electrolysis is in the range of 20V to 30V.

59. The method as claimed in claim 54 wherein electrolysis is controlled to achieve an insulating layer film formation rate in the range of 40 to 50 μm/hr.

60. The method as claimed in claim 38, wherein the insulating layer thickness is in the range of 1 to 100 μm.

61. The method as claimed in claim 38, wherein the insulating layer thickness is in the range of 10 to 30 μm.

62. The method as claimed in claim 54, wherein the substrate base with insulating layer is treated post-anodising by heat treatment by storage in an oven at a temperature in the range of 70° C. to 90° C.

63. The method as claimed in claim 38, wherein the insulating layer is selectively metal coated by initially applying a blanket metal coating and subsequently selectively removing the metal.

64. The method as claimed in claim 63, wherein the blanket of metal is applied by sputtering.

65. The method as claimed in claim 63, wherein the metal blanket is treated by photolithography and chemical etching.

66. The method as claimed in claim 63, wherein the metal blanket is selectively abraded to expose the underlying insulating layer, said abrasion including co-planar raised surfaces.

67. The method as claimed in claim 38, wherein the substrate base comprises an aluminium layer over a different metal.

68. The method of producing an illuminator comprising the steps of:
producing a substrate in a method of claim 38,
placing bare die light emitting diodes in the cavities, and
placing wire bonds between the diodes and the tracks.

69. An illuminator substrate comprising:
a substrate base comprising at least a layer of aluminium having a surface, said surface being structured with cavities for bare die light emitting diodes and recesses for electrical tracks,
an insulating layer of aluminium oxide over the substrate base; and
conductive pads in the cavities and tracks in the track recesses on the insulating layer.
